(19) United States
(12) Patent Application Publication
(10) Pub. No.: US 2026/0157126 A1
(43) Pub. Date: Jun. 4, 2026

(54) METHOD AND SYSTEM FOR FORMING A MOLYBDENUM-CONTAINING LAYER AND STRUCTURE FORMED USING THE SAME

(71) Applicant: ASM IP Holding B.V., Almere (NL)

(72) Inventors: Antareep Sharma, Helsinki (FI); Chiyu Zhu, Helsinki (FI); Jan Willem Maes, Wilrijk (BE)

(21) Appl. No.: 19/403,094

(22) Filed: Nov. 27, 2025

Related U.S. Application Data
(60) Provisional application No. 63/726,490, filed on Nov. 30, 2024.

(51) Int. Cl. H10P 14/43; C23C 16/02; C23C 16/42; H10D 64/01; H10P 14/40

(52) U.S. Cl. CPC H10P 14/432; C23C 16/0227; C23C 16/42; H10D 64/0112; H10P 14/414; H10P 14/418

(57) ABSTRACT

The current disclosure relates to method for selectively filling a gap on substrate with a material comprising molybdenum. In the method, molybdenum-containing material is deposited into a gap by a cyclic deposition process. The method comprises providing a substrate into a reaction chamber, wherein the substrate comprises at least one gap and wherein the gap comprises a silicon surface and a dielectric surface. The method further comprises executing at least one deposition cycle. A deposition cycle comprises providing a molybdenum precursor into the reaction chamber in vapor phase and providing a reactant into the reaction chamber in vapor phase. The molybdenum-containing material is selectively deposited on the silicon surface of the gap to at least partially fill the gap. The disclosure further relates to a semiconductor processing apparatus for filling a gap with a molybdenum-containing material.

### CROSS-REFERENCE TO RELATED APPLICATIONS

The present application claims priority to and the benefit of U.S. Provisional Application No. 63/726,490, filed November 30, 2024, the entirety of which is hereby incorporated by reference.

### FIELD OF INVENTION

The present disclosure relates to methods and apparatuses for the manufacture of semiconductor devices. More particularly, the disclosure relates to methods and assemblies for depositing molybdenum-containing material on a substrate, and layers comprising molybdenum.

### BACKGROUND OF THE DISCLOSURE

Metal silicides can be formed in the fabrication of various semiconductor devices. Low resistivity materials for contacts, vias and general fills are a highly appealing area of focus for logic/DRAM applications. Molybdenum and molybdenum silicides are excellent materials for such applications.

### SUMMARY OF THE DISCLOSURE

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

Any discussion, including discussion of problems and solutions, set forth in this section has been included in this disclosure solely for the purpose of providing a context for the present disclosure. Such discussion should not be taken as an admission that any or all of the information was known at the time the invention was made or otherwise constitutes prior art.

Various embodiments of the present disclosure relate to methods for filling a gap, to structures and devices formed using such methods, and to apparatus for performing the methods and/or for forming the structures and/or devices. The materials may be used in the field of integrated circuit manufacture.

Thus described herein is a method for selectively filling a gap with molybdenum-containing material. The method comprises providing a substrate into a reaction chamber, wherein the substrate comprises at least one gap, and wherein the gap comprises a silicon surface and a dielectric surface; and executing at least one deposition cycle. Each deposition cycle comprises providing a molybdenum precursor into the reaction chamber in vapor phase; and providing a reactant into the reaction chamber in vapor phase. This way the molybdenum-containing material is selectively deposited on the silicon surface of the gap to at least partially fill the gap.

In some embodiments, the method further comprises a thermal anneal step, wherein the substrate is heated to a temperature of at least 550 °C.

In some embodiments, the substrate is heated to a temperature between 350 °C and 550 °C during a deposition cycle.

In some embodiments, the deposited molybdenum-containing material comprises molybdenum silicide.

In some embodiments, the method further comprises precleaning the silicon-containing substrate to remove native oxide from the surface of the substrate. In some embodiments, the preclean is performed by remote plasma treatment, radical treatment, hydrogen fluoride treatment or sputter etch. In some embodiments, the radical treatment comprises treating the surface with radicals obtained from NH₃ gas and/or NF₃ gas.

In some embodiments, the method further comprises a purge step after providing the molybdenum precursor and after providing the reactant.

In some embodiments, the molybdenum precursor is provided into the reaction chamber in pulses and the reactant is provided into the reaction chamber continuously.

In some embodiments, the gap comprises a bottom and at least two sidewalls (sidewalls), wherein the bottom comprises silicon, silicon-germanium, germanium, or doped forms thereof, and wherein the at least two sidewalls comprise a dielectric material. In some embodiments, the dielectric material comprises silicon oxynitride. In some embodiments, the dielectric material comprises silicon oxide. In some embodiments, the dielectric material comprises silicon nitride. In some embodiments, the dielectric material comprises silicon oxycarbide. In some embodiments, the dielectric material comprises aluminum oxide.

In some embodiments, the gap may be vertically or horizontally oriented relative to a proximal surface of the substrate.

In some embodiments, the method further comprises depositing a second material into the gap, wherein the second material comprises metallic molybdenum. In some embodiments, the second material is deposited on top of the molybdenum-containing material.

In some embodiments, the second material is deposited by executing at least one deposition cycle, wherein a deposition cycle comprises: providing a molybdenum precursor into the reaction chamber in vapor phase; and providing a reactant into the reaction chamber in vapor phase, wherein the pressure in the reaction chamber is higher during deposition of the second material than during deposition of molybdenum-containing material.

In some embodiments, the molybdenum precursor comprises a molybdenum halide. In some embodiments, the molybdenum halide comprises molybdenum pentachloride.

In some embodiments, the reactant comprises hydrogen.

In another aspect of the invention, a semiconductor processing apparatus is described. The apparatus comprises a reaction chamber comprising a substrate support for supporting a substrate; a heater constructed and arranged to heat the substrate in the reaction chamber; a molybdenum precursor source containing a molybdenum precursor in fluid connection with the reaction chamber via one or more precursor valves; a reactant source containing a reactant in fluid connection with the reaction chamber via one or more reactant valves; and a controller configured and/or programmed for causing the semiconductor processing apparatus to perform a method according to the description herein.

### BRIEF DESCRIPTION OF THE DRAWING FIGURES

The accompanying drawings, which are included to provide a further understanding of the disclosure and constitute a part of this specification, illustrate exemplary embodiments, and together with the description help explain the principles of the disclosure. In the drawings:

FIG. 1A-1B illustrate embodiments of a method according to the current disclosure.

FIG. 2 depicts a structure according to an aspect of the current disclosure.

FIG. 3 presents a semiconductor processing apparatus according to the current disclosure in a schematic manner.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below.

As used herein, the term “substrate” may refer to any underlying material or materials, including any underlying material or materials that may be modified, or upon which, a device, a circuit, or a film may be formed. The “substrate” may be continuous or non-continuous; rigid or flexible; solid or porous; and combinations thereof. The substrate may be in any form, such as a powder, a plate, or a workpiece. Substrates in the form of a plate may include wafers in various shapes and sizes. Substrates may be made from semiconductor materials, including, for example, silicon, silicon germanium, germanium, silicon oxide, gallium arsenide, gallium nitride, or silicon carbide.

By way of example, a substrate in the form of a powder may have applications for pharmaceutical manufacturing. A porous substrate may comprise polymers. Examples of workpieces may include medical devices (for example, stents and syringes), jewelry, tooling devices, components for battery manufacturing (for example, anodes, cathodes, or separators) or components of photovoltaic cells and the like.

A continuous substrate may extend beyond the bounds of a process chamber where a deposition process occurs. In some processes, the continuous substrate may move through the process chamber such that the process continues until the end of the substrate is reached. A continuous substrate may be supplied from a continuous substrate feeding system to allow for manufacture and output of the continuous substrate in any appropriate form.

Non-limiting examples of a continuous substrate may include a sheet, a non-woven film, a roll, a foil, a web, a flexible material, a bundle of continuous filaments or fibers (for example, ceramic fibers or polymer fibers). Continuous substrates may also comprise carriers or sheets upon which non-continuous substrates are mounted.

The terms “precursor” and “reactant” can refer to molecules (compounds or molecules comprising a single element) that participate in a chemical reaction that produces another compound or element. A precursor typically contains portions that are at least partly incorporated into the compound or element resulting from the chemical reaction in question. Such a resulting compound or element may be deposited on a substrate. A reactant may be an element or a compound that is not incorporated into the resulting compound or element to a significant extent. The terms precursor and reactant can be used interchangeably.

In some embodiments, a precursor or a reactant is provided in a mixture of two or more compounds. In a mixture, the other compounds in addition to the precursor or reactant may be inert compounds or elements. In some embodiments, a precursor or a reactant is provided in a composition. The composition may be a solution or a gas under standard conditions.

A vapor deposition method according to the current disclosure refers to processes in which material is deposited on the substrate from gas phase.

Generally, cyclic deposition processes according to the current disclosure, such as atomic layer deposition (ALD) and molecular layer deposition (MLD), include one or more deposition cycles. During each cycle, a precursor is introduced to a reaction chamber and is chemisorbed to a substrate surface (which may include a substrate surface that may include a previously deposited material from a previous deposition cycle or other material). In some embodiments, the precursor on the substrate surface does not readily react with additional precursor (i.e., the deposition of the precursor may be a partially or fully self-limiting reaction). Thereafter, another precursor or a reactant may be introduced into the reaction chamber for converting the chemisorbed precursor to the desired material on the deposition surface. The reactant may be capable of further reaction with the precursor. Purging steps may be utilized during one or more cycles, e.g., during each step of each cycle or after each cycle, to remove any excess precursor from the process chamber and/or remove any excess reactant and/or reaction byproducts from the reaction chamber. Thus, in some embodiments, the cyclic deposition process comprises purging the reaction chamber after providing a precursor into the reaction chamber. In some embodiments, the cyclic deposition process comprises purging the reaction chamber after providing a molybdenum precursor into the reaction chamber. In some embodiments, the cyclic deposition process comprises purging the reaction chamber after providing a reactant into the reaction chamber. In some embodiments, the cyclic deposition process comprises purging the reaction chamber after providing a molybdenum precursor into the reaction chamber, and after providing reactant into the reaction chamber into the reaction chamber. Without limiting the current disclosure to any specific theory, ALD and MLD may be similar processes in terms of self-limiting reactions, and slower and more controllable layer growth speed compared to CVD. Generally, ALD is used to deposit inorganic materials, whereas in MLD, precursors may generally comprise organic molecules, although it is understood the present invention is not so limited in the use of ALD or MLD.

The process may comprise one or more cyclic phases. In some embodiments, the process comprises one or more acyclic (i.e., continuous) phases. In some embodiments, the deposition process comprises the continuous flow of at least one precursor. In some embodiments, the process comprises a continuous flow of a first precursor and/or a second precursor. In some embodiments, one or more of precursors are provided in the reaction chamber continuously.

In some embodiments, at least one of a molybdenum precursor and a reactant is provided to the reaction chamber in pulses. In some embodiments, the molybdenum precursor is supplied in pulses and the reactant is supplied in pulses, and the reaction chamber is purged between consecutive pulses of molybdenum precursor and reactant. A duration of providing molybdenum precursor and/or a reactant into the reaction chamber (i.e., molybdenum precursor pulse time and reactant pulse time, respectively) may be, for example, from about 0.01 seconds (s) to about 100s, for example, from about 0.01 s to about 5 s, or from about 1 s to about 20s, or from about 0.5s to about 10s, or from about 5 s to about 15s, or from about 10s to about 30s, or from about 10s to about 60s, or from about 20 s to about 60 s. The duration of molybdenum precursor or a reactant pulse may be, for example, 0.03 s, 0.1 s, 0.5 s, 1 s, 1.5 s, 2 s, 2.5 s, 3 s, 4 s, 5s, 8s, 10s, 12s, 15s, 25 s, 30 s, 40s, 50 s, 60 s, 80 s, or 100s.

In some embodiments, a molybdenum precursor pulse time may be at least 5 seconds, or at least 10 seconds. In some embodiments, a molybdenum precursor pulse time may be at most 5 seconds, or at most 10 seconds or at most 20 seconds, or at most 30 seconds. In some embodiments, a reactant pulse time may be at least 5 seconds, or at least 10 seconds, or at least 20 seconds. In some embodiments, a reactant pulse time may be at most 5 seconds, or at most 10 seconds or at most 20 seconds, or at most 30 seconds.

The pulse times for a molybdenum precursor, and for a reactant vary independently according to process in question. In some embodiments, the selection of an appropriate pulse time may depend on the substrate topology. For higher aspect ratio structures, longer pulse times may be needed to obtain sufficient surface saturation in different areas of a high aspect ratio structure. Also, the selected molybdenum precursor and reactant chemistries may influence suitable pulsing times. For process optimization purposes, shorter pulse times might be preferred as long as appropriate layer properties can be achieved. In some embodiments, a molybdenum precursor pulse time is longer than a reactant pulse time. In some embodiments, a reactant pulse time is longer than a molybdenum precursor pulse time. In some embodiments, a molybdenum precursor pulse time is the same as a reactant pulse time.

In some embodiments, providing a molybdenum precursor and/or a reactant into the reaction chamber comprises pulsing the molybdenum precursor and the reactant over a substrate. In certain embodiments, pulse times in the range of several minutes may be used for the molybdenum precursor and/or the reactant. In some embodiments, molybdenum precursor may be pulsed more than one time, for example two, three or four times, before a reactant is pulsed to the reaction chamber. Similarly, there may be more than one pulse, such as two, three or four pulses, of a reactant before molybdenum precursor is pulsed (i.e., provided) into the reaction chamber.

As used herein, the term “purge” refers to a procedure in which vapor phase precursors and/or vapor phase byproducts are removed from the substrate surface, for example, by evacuating the reaction chamber with a vacuum pump and/or by replacing the gas inside a reaction chamber with an inert or substantially inert gas, such as argon or nitrogen. Purging may be effected between two pulses of gases which react with each other. However, purging may be effected between two pulses of gases that do not react with each other. For example, a purge, or purging may be provided between pulses of two precursors or between a precursor and a reactant. Purging may avoid or at least reduce gas-phase interactions between the two gases reacting with each other. It shall be understood that a purge can be effected either in time or in space, or both. For example, in the case of temporal purges, a purge step can be used, e.g., in the temporal sequence of providing a first precursor to a reaction chamber, providing a purge gas to the reaction chamber, and providing a second precursor to the reaction chamber, wherein the substrate on which a layer is deposited does not move. In the case of spatial purges, a purge step can take the following form: moving a substrate from a first location to which a first precursor is continually supplied, through a purge gas curtain or another method for separating the two spaces, to a second location to which a second precursor is continually supplied. Purging times may be, for example, from about 0.01 seconds to about 60 seconds, from about 0.05s to about 50s, or from about 1s to about 40s, or from about 0.5 s to about 30s, or between about 1 s and about 45 seconds, such as 20s, 30 s or 40 s. However, other purge times can be utilized if necessary, such as where highly conformal step coverage over extremely high aspect ratio structures or other structures with complex surface morphology is needed, or in specific reactor types, such as a batch reactor, may be used.

CVD-type processes may be characterized by vapor deposition which is not self-limiting. They typically involve gas phase reactions between two or more precursors and/or reactants. In some embodiments, CVD-type processes involve surface reactions or surface decomposition of two or more precursors and/or reactants. The precursor(s) and reactant(s) can be provided simultaneously to the reaction space or substrate, or in partially or completely separated pulses. However, CVD may be performed with a single precursor, or two or more precursors that do not react with each other. The single precursor may decompose into reactive components that are deposited on the substrate surface. The decomposition may be brought about by plasma or thermal methods, for example. The substrate and/or reaction space can be heated to promote the reaction between the gaseous precursor and/or reactants. In some embodiments, the precursor(s) and reactant(s) are provided until a layer having a desired thickness is deposited. In some embodiments, cyclic CVD processes can be used with multiple cycles to deposit a thin film having a desired thickness. In cyclic CVD processes, the precursors and/or reactants may be provided to the reaction chamber in pulses that do not overlap, or that partially or completely overlap.

As used herein, the term “layer” or “film” can refer to any continuous or non-continuous material, such as material deposited by the methods disclosed herein. For example, a layer or film can include two-dimensional materials, three-dimensional materials, nanoparticles or even partial or full molecular layers or partial or full atomic layers or clusters of atoms and/or molecules. A film or layer may comprise material or a layer with pinholes, which may be at least partially continuous. In some embodiments, a layer according to the current disclosure is substantially continuous.

In this disclosure, “gas” can include material that is a gas at normal temperature and pressure (NTP), a vaporized solid and/or a vaporized liquid, and can be constituted by a single gas or a mixture of gases, depending on the context. A passivation material precursor may be provided to the reaction chamber in gas phase. A hard mask precursor may be provided to the reaction chamber in gas phase. The term “inert gas” can refer to a gas that does not take part in a chemical reaction and/or does not become a part of a layer to an appreciable extent. Exemplary inert gases include He, Ar, and any combination thereof. In some cases, molecular nitrogen and/or hydrogen can be an inert gas. A gas other than a process gas, i.e., a gas introduced without passing through a precursor injector system, other gas distribution device, or the like, can be used for, e.g., sealing the reaction space, and can include a seal gas.

A method of depositing molybdenum-containing material according to the current disclosure comprises providing a substrate in a reaction chamber. In other words, a substrate is in a space where the deposition conditions can be controlled. The reaction chamber may be a single wafer reactor. Alternatively, the reaction chamber may be a batch reactor. The reaction chamber can form part of a vapor processing assembly for manufacturing semiconductor devices. The processing assembly may comprise one or more multi-station processing chambers. In some embodiments, the substrate is moved between processing stations of a multi-station processing chamber. The reaction chamber may be part of a cluster tool in which different processes are performed to form an integrated circuit. Various phases of a method as disclosed herein can be performed within a single reaction chamber, or they can be performed in multiple reaction chambers, such as reaction chambers of a cluster tool, or deposition stations of a multi-station processing chamber.

In some embodiments, the reaction chamber may be a flow-type reactor, such as a cross-flow reactor. In some embodiments, the reaction chamber may be a showerhead reactor. In some embodiments, the reaction chamber may be a hot-wall reactor. In some embodiments, the reaction chamber may be a space-divided reactor. In some embodiments, the reaction chamber may be single wafer ALD reactor. In some embodiments, the reaction chamber may be a high-volume manufacturing single wafer ALD reactor. In some embodiments, the reaction chamber may be a batch reactor for manufacturing multiple substrates simultaneously.

The reaction chamber can form part of an atomic layer deposition (ALD) assembly. The reaction chamber can form part of a chemical vapor deposition (CVD) assembly. The semiconductor processing apparatus may be an ALD or a CVD semiconductor processing apparatus. In some embodiments, the method is performed in a single reaction chamber of a cluster tool, but other, preceding or subsequent, manufacturing steps of the structure or device are performed in additional reaction chambers of the same cluster tool. Optionally, an assembly including the reaction chamber can be provided with a heater to activate the reactions by elevating the temperature of one or more of the substrate and/or the reactants and/or precursors.

As used herein, the term “comprising” indicates that certain features are included, but that it does not exclude the presence of other features, as long as they do not render the claim unworkable. The term “comprising” includes but is not limited to “consisting of” or “consisting essentially of”.

As used herein, the term “consisting” indicates that no further features are present in the apparatus/method/product apart from the ones following said wording. When the term “consisting” is used referring to a chemical compound, substance, or composition of matter, it indicates that the chemical compound, substance, or composition of matter only contains the components which are listed. Likewise, when the term “consisting essentially” is used referring to a chemical compound, substance, or composition of matter, it indicates that the chemical compound, substance, or composition of matter contains the components which are listed but can also containing trace elements and/or impurities that do not materially affect the characteristics of said chemical compound, substrate, or composition of matter. This notwithstanding, the chemical compound, substance, or composition of matter may, in some embodiments, comprise other components as trace elements or impurities, apart from the components that are listed.

Further, in this disclosure, any two numbers of a variable can constitute a workable range of the variable, and any ranges indicated may include or exclude the endpoints. Additionally, any values of variables indicated (regardless of whether they are indicated with “about” or not) may refer to precise values or approximate values and include equivalents, and may refer to average, median, representative, majority, or the like. Further, in this disclosure, the terms “including,” “constituted by” and “having” refer independently to “typically or broadly comprising,” “comprising,” “consisting essentially of,” or “consisting of” in some embodiments. In this disclosure, any defined meanings do not necessarily exclude ordinary and customary meanings in some embodiments.

“At least one”, “one or more”, and “and/or” are open-ended expressions that are both conjunctive and disjunctive in operation. For example, each of the expressions “at least one of A, B, and C”, “at least one of A, B, or C”, “one or more of A, B, and C”, “one or more of A, B, or C” and “A, B, and/or C” means A alone, B alone, C alone, A and B together, A and C together, B and C together, or A, B and C together. When each one of A, B, and C in the above expressions refers to an element, such as X, Y, and Z, or class of elements, such as X1-Xn, Y1-Ym, and Z1-Zo, the phrase is intended to refer to a single element selected from X, Y, and Z, a combination of elements selected from the same class (e.g., X1 and X2) as well as a combination of elements selected from two or more classes (e.g., Y1 and Zo).

In the present disclosure, it will be understood that the term “on” or “over” may be used to describe a relative location relationship. Another element, film or layer may be directly on the mentioned layer, or another layer (an intermediate layer) or element may be intervened therebetween, or a layer may be disposed on a mentioned layer but not completely cover a surface of the mentioned layer. Therefore, unless the term “directly” is separately used, the term “on” or “over” will be construed to be a relative concept. Similarly to this, it will be understood the term “under”, “underlying”, or “below” will be construed to be relative concepts.

The term "substantially" as applied to a composition, a method, or a system generally refers to a proportion of a value, a property, a characteristic, or the like, or conversely a lack thereof, that is at least about 70%, at least about 80%, at least about 90%, at least about 95%, at least about 97%, at least about 98%, at least about 99%, at least about 99.5%, at least about 99.9%, or more, or any proportion between about 70% and about 100%. In some embodiments, the term "substantially" means a proportion of about 90%, about 95%, about 97%, about 98%, about 99%, about 99.5%, or about 99.9%.

The term "essentially" as applied to a composition, a method, or a system generally means that the additional components do not substantially modify the properties and/or function of the composition, the method, or the system.

As used herein, “molybdenum precursor” includes a gas or a material that can become gaseous and that can be represented by a chemical formula that includes molybdenum. In some embodiments, the molybdenum precursor comprises a molybdenum halide. In some embodiments, the molybdenum precursor is selected from the group consisting of molybdenum pentachloride, molybdenum hexafluoride, molybdenum oxytetrachloride and molybdenum dichloride dioxide. In some embodiments, the molybdenum precursor is provided in a mixture of two or more compounds. In a mixture, the other compounds in addition to the molybdenum precursor is provided in a composition. Compositions suitable for use as composition can include a molybdenum compound and an effective amount of one or more stabilizing agents. The compositions may be a solution or a gas in standard conditions.

In some embodiments, the molybdenum precursor is provided to the reactor chamber at a temperature from about 300 °C to about 550 °C. In some embodiments, molybdenum-containing material may be deposited at a temperature from about 325 °C to about 500 °C, or at a temperature from about 350 °C to about 450 °C. In some embodiments, molybdenum-containing material may be deposited at a temperature from about 360 °C to about 430 °C, or at a temperature from about 370 °C to about 430 °C. In some embodiments, molybdenum-containing material may be deposited at a temperature from about 300 °C to about 400 °C, or at a temperature from about 350 °C to about 400 °C, or at a temperature from about 380 °C to about 420 °C. In some embodiments, molybdenum-containing material may be deposited at a temperature of about 310 °C or about 325 °C or about 385 °C, or about 390 °C, or about 410 °C, or about 415 °C or about 425 °C, or about 375 °C, or about 380 °C, or about 385 °C, or about 390 °C.

In some embodiments, the reactant is provided to the reactor chamber at a temperature from about 300 °C to about 550 °C. In some embodiments, reactant may be provided at a temperature from about 325 °C to about 500 °C. In some embodiments, reactant may be provided at a temperature from about 360 °C to about 430 °C, or at a temperature from about 370 °C to about 430 °C. In some embodiments, reactant may be provided at a temperature from about 300 °C to about 400 °C, or at a temperature from about 350 °C to about 400 °C, or at a temperature from about 380 °C to about 420 °C. In some embodiments, reactant may be provided at a temperature of about 310 °C or about 325 °C or about 385 °C, or about 390 °C, or about 410 °C, or about 415 °C or about 425 °C, or about 375 °C, or about 380 °C, or about 385 °C, or about 390 °C.

A pressure in a reaction chamber may be selected independently for different process steps. In some embodiments, a first pressure may be used during molybdenum precursor pulse, and a second pressure may be used during reactant pulse. A third or a further pressure may be used during purging or other process steps. In some embodiments, a pressure within the reaction chamber during the deposition process is at atmospheric pressure, or less than 760 Torr, or wherein a pressure within the reaction chamber during the deposition process is between 0.2 Torr and 760 Torr, or between 1 Torr and 100 Torr, or between 1 Torr and 10 Torr. In some embodiments, a pressure within the reaction chamber during the deposition process is less than about 0.001 Torr, less than 0.01 Torr, less than 0.1 Torr, less than 1 Torr, less than 10 Torr, less than 50 Torr, less than 100 Torr or less than 300 Torr. In some embodiments, a pressure within the reaction chamber during at least a part of the method according to the current disclosure is less than about 0.001 Torr, less than 0.01 Torr, less than 0.1 Torr, less than 1 Torr, less than 10 Torr or less than 50 Torr, less than 100 Torr or less than 300 Torr. In some embodiments, a first pressure may be about 0.1 Torr, about 0.5 Torr, about 1 Torr, about 5 Torr, about 10 Torr, about 20 Torr or about 50 Torr. In some embodiments, a second pressure is about 0.1 Torr, about 0.5 Torr, about 1 Torr, about 5 Torr, about 10 Torr, about 20 Torr or about 50 Torr.

In some embodiments, the molybdenum precursor and reactant are supplied in pulses, reactant is supplied in pulses and the reaction chamber is purged between consecutive pulses of molybdenum precursors and reactants. The length of a molybdenum precursor pulse or a reactant pulse may be from about 0.01 s to about 120 s, for example, from about 0.01 s to about 5 s, or from about 1 s to about 20 s, or from about 0.5 s to about 10 s, or from about 5 s to about 15 s, or from about 10 s to about 30 s, or from about 10 s to about 60 s, or from about 20 s to about 60 s. The length of a molybdenum precursor or a reactant pulse may be, for example, 0.03 s, 0.1 s, 0.5 s, 1s, 1.5 s, 2 s, 2.5 s, 3 s, 4 s, 5 s, 8 s, 10 s, 12 s, 15 s, 25 s, 30 s, 40 s, 50 s or 60 s. In some embodiments, molybdenum precursor pulse time may be at least 5 seconds, or at least 10 seconds, or at least 20 seconds, or at least 30 seconds. In some embodiments, molybdenum precursor pulse time may be at most 5 seconds, or at most 10 seconds or at most 20 seconds, or at most 30 seconds. In some embodiments, reactant pulse time may be at least 20 seconds, or at least 30 seconds, or at least 45 seconds, or at least 60 seconds. In some embodiments, reactant pulse time may be at most 90 seconds, or at most 100 seconds or at most 110 seconds, or at most 120 seconds.

The pulse times for molybdenum precursor and reactant vary independently according to process in question. The selection of an appropriate pulse time may depend on the substrate topology. For higher aspect ratio structures, longer pulse times may be needed to obtain sufficient surface saturation in different areas of a high aspect ratio structure. Also, the selected molybdenum precursor and reactant chemistries may influence suitable pulsing times. For process optimization purposes, shorter pulse times might be preferred as long as appropriate layer properties can be achieved. In some embodiments, molybdenum precursor pulse time is longer than reactant pulse time. In some embodiments, reactant pulse time is longer than molybdenum precursor pulse time. In some embodiments, molybdenum precursor pulse time is same as reactant pulse time.

In some embodiments, the reactant is provided into the reaction chamber as a continuous flow and the molybdenum precursor is provided into the reaction chamber as pulses. This pulsing scheme can be referred to as semi-CVD or pulsed CVD. The continuous flow and the pulses at least partially overlap. There is an interval between pulses such that a substrate is exposed to a precursor during pulses.

In some embodiments, molybdenum precursor may be pulsed more than one time, for example, two, three or four times, before a reactant is pulsed to the reaction chamber. Similarly, there may be more than one pulse, such as two, three or four pulses, of a reactant before molybdenum precursor is pulsed (i.e., provided) to the reaction chamber.

In some embodiments, the formed molybdenum-containing material may comprise molybdenum silicide. The silicide is formed when the molybdenum-containing material is deposited into the gap and it is thermally annealed which causes the molybdenum to intermix with a silicon surface in the bottom of the gap. In other words, the deposited molybdenum-containing material uses the silicon from the silicon substrate to form molybdenum silicide when heated. In some embodiments, a layer of molybdenum silicide is deposited into the gap. In some embodiments, on top of the molybdenum silicide, a layer of metallic molybdenum may be deposited into the gap. The metallic molybdenum is deposited by using the same molybdenum precursor and reactant as in the deposition of molybdenum silicide. The metallic molybdenum is deposited in a pressure about 50 torr higher than the molybdenum silicide. As used herein, “metallic molybdenum” refers to molybdenum deposited in its zero-oxidation-state form, not present as a compound.

In some embodiments, the deposition process is a selective process. The gap is formed from two different materials and the deposited molybdenum-containing material only grows on one of them. In some embodiments, at least one surface of the gap is formed from a material selected from a group consisting of silicon, silicon-germanium and germanium, and at least one surface is formed from a dielectric material. In some embodiments, the material comprising silicon or silicon-germanium or germanium is doped with an element selected from the group consisting of boron, phosphorous, arsenic and gallium. In some embodiments, the molybdenum-containing material grows on the silicon surface and does not grow on the dielectric surface. In some embodiments, a bottom of the gap is silicon and at least one, e.g., at least two sidewalls, at least three, or at least four sidewalls, comprise a dielectric material. In some embodiments, the orientation of the gap can be horizontal relative to a proximal surface of the substrate. In some embodiments, the orientation of the gap can be vertical relative to a proximal surface of the substrate. Regardless of the orientation of the gap, the bottom of the gap is located opposite to the opening of the gap with sidewalls perpendicular to the bottom.

In some embodiments, the method comprises removing excess molybdenum precursor from the reaction chamber by an inert gas prior to providing the reactant in the reaction chamber. In some embodiments, the reaction chamber is purged between providing a molybdenum precursor in a reaction chamber and providing a reactant in the reaction chamber. In some embodiments, there is a purge step between every pulse. Thus, the reaction chamber may be purged also between two pulses of the same chemistry, such as a molybdenum precursor or a reactant.

According to another aspect of the current disclosure, there is provided a semiconductor processing apparatus for filling a gap on a substrate with a molybdenum-containing material. The apparatus comprises one or more reaction chambers constructed and arranged to hold the substrate, a precursor injector system constructed and arranged to provide a molybdenum precursor and a reactant into the reaction chamber in a vapor phase. The apparatus further comprises a first precursor vessel constructed and arranged to contain and evaporate a molybdenum. The semiconductor processing apparatus further comprises a second precursor vessel constructed and arranged to contain and evaporate a reactant. The deposition assembly comprises a controller that is constructed and arranged to provide the molybdenum precursor and the reactant via the precursor injector system to the reaction chamber to fill a gap on a substrate with a molybdenum-containing material.

In some embodiments, the apparatus further comprises a temperature controller for controlling the temperature of the reaction chamber. The temperature in the reaction chamber can be set to be between 350 °C and 550 °C as described in the above disclosure. In some embodiments, the temperature controller is a heater constructed and arranged to heat the substrate in the reaction chamber.

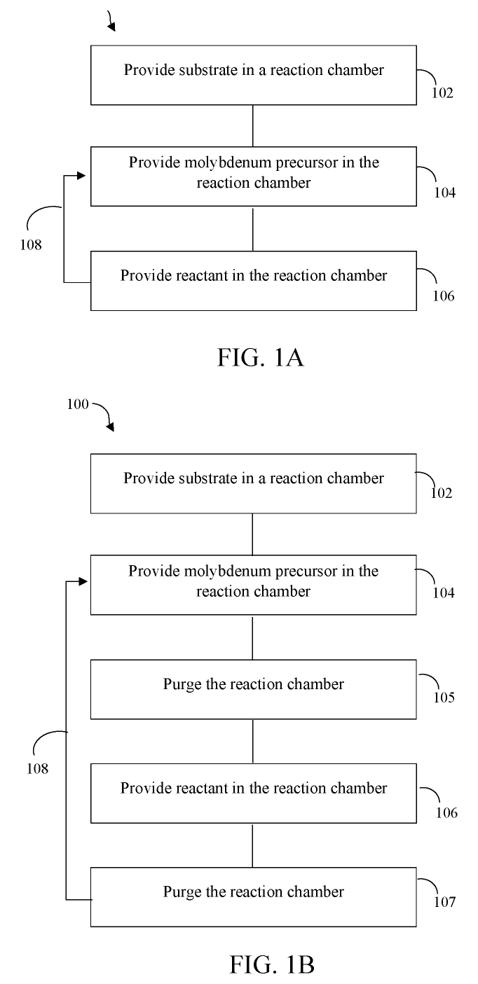

FIG. 1, panels A and B (FIGS. 1A and 1B), illustrate embodiments of a method 100 according to the current disclosure. Referring to FIG. 1A, the method 100 may be used to fill a gap with a material comprising molybdenum. The material can be used during a formation of a structure or a device. However, methods are not limited to such applications.

During step 102, a substrate is provided into a reaction chamber of a reactor. The reaction chamber can form part of an atomic layer deposition (ALD) reactor. The reactor may be a single wafer reactor. Alternatively, the reactor may be a batch reactor. Various phases of method 100 can be performed within a single reaction chamber or they can be performed in multiple reactor chambers, such as reaction chambers of a cluster tool. In some embodiments, the method 100 is performed in a single reaction chamber of a cluster tool, but other, preceding or subsequent, manufacturing steps of the structure or device are performed in additional reaction chambers of the same cluster tool. Optionally, a reactor including the reaction chamber can be provided with a heater to activate the reactions by elevating the temperature of one or more of the substrate and/or the reactant(s) and/or precursor(s).

During step 102, the substrate can be brought to a desired temperature and pressure for providing molybdenum precursor in the reaction chamber 104 and/or for providing reactant in the reaction chamber 106. A temperature (e.g., of a substrate or a substrate support) within a reaction chamber can be, for example, from about 300 °C to about 550 °C, or from about 350 °C to about 500°C. In some embodiments, a temperature within a reaction chamber can be from about 375 °C to about 425 °C, or from about 380 °C to about 420 °C. In some embodiments, the temperature within the reaction chamber may be about 310 °C or about 325 °C or about 385 °C, or about 390 °C, or about 410 °C, or about 415 °C or about 425 °C, or about 375 °C, or about 380 °C, or about 385 °C, or about 390 °C. In some embodiments, if the temperature is lower than 300 or 350 °C, the growth rate of the deposited material decreases.

A pressure within the reaction chamber can be less than 760 Torr, for example, 400 Torr, 100 Torr, 70 Torr or 20 Torr, 5 Torr, Torr or 0.1 Torr. Different pressure may be used for different process steps. In some embodiments, the pressure is kept at a pressure for about 200 deposition cycles and then the pressure is increased by about 50 Torr for about 400 deposition cycles. In some embodiments, this pressure change enables the deposition of a dual layer, wherein the layer first deposited comprises molybdenum silicide and the layer second deposited comprises metallic molybdenum.

Molybdenum precursor is provided in the reaction chamber containing the substrate 104. Without limiting the current disclosure to any specific theory, molybdenum precursor may chemisorb on the substrate during providing molybdenum precursor in the reaction chamber. The duration of providing molybdenum precursor in the reaction chamber (molybdenum precursor pulse time) may be, for example, 0.01s, 0.5 s,1s, 1.5s, 2s, 2.5s, 3s, 3.5s, 4s, 4.5 s or 5 s. In some embodiments, the duration of providing molybdenum precursor in the reaction chamber (molybdenum precursor pulse time) may be more than 0.01s, more than 0.5s, or about 1s.

When reactant is provided in the reaction chamber 106, it may react with the chemisorbed molybdenum precursor, or its derivate species, to form a material comprising molybdenum. The duration of providing reactant in the reaction chamber (reactant pulse time) may be, for example, 0.5 s, 1 s, 2 s, 3 s, 3.5 s, 4 s, 5 s, 6 s, 7 s, 8 s, 10 s, 12 s, 15 s, 30 s, 40 s, 50 s or 60 s. In some embodiments, the duration of providing reactant in the reaction chamber may be less than 30 s, less than 20 s, or about 10 s.

In some embodiments, molybdenum precursor may be heated before providing it into the reaction chamber. In some embodiments, the reactant may be heated before providing it to the reaction chamber. In some embodiments, the reactant may be kept at ambient temperature before providing it to the reaction chamber.

Steps 104 and 106, performed in any order, may form a deposition cycle, resulting in the deposition of a material comprising molybdenum. In some embodiments, the two steps of the deposition, namely providing the molybdenum precursor and the reactant in the reaction chamber (104 and 106), may be repeated (loop 108). Such embodiments contain several deposition cycles. The thickness of the deposited material may be regulating by adjusting the number of deposition cycles. The deposition cycle (loop 108) may be repeated until a desired material thickness is achieved. In some embodiments, about 50, 100, 150, 200, 250, 300, 400, 500, 600, 700, 800, 1,200 or 1,500 deposition cycles may be performed.

The amount of molybdenum-containing material deposited during one cycle (growth per cycle) varies depending on the process conditions, and may be, for example from about 0.1 Å/cycle to about 10 Å/cycle, like from about 0.3 Å/cycle to about 4.5 Å/cycle, such as from about 0.5 Å/cycle to about 3.5 Å/cycle or from about 1.2 Å/cycle to about 3.0 Å/cycle. In some embodiments, the growth rate may be about 1.0 Å/cycle, 1.2 Å/cycle, 1.4. Å/cycle, 1.6 Å/cycle, 1.8 Å/cycle, 2 Å/cycle, 2.2 Å/cycle, 2.4 Å/cycle. Depending on the deposition conditions or deposition cycle numbers, material of variable thickness may be deposited. In some embodiments, the deposited material may have a thickness between approximately 0.2 nm and 60 nm, or between about 1nm and 50 nm, or between about 0.5 nm and 25 nm, or between about 1 nm and 50 nm, or between about 10 nm and 60 nm. In some embodiments, the deposited material may have a thickness of approximately 0.2 nm, 0.3 nm, 0.5 nm, 1 nm, 1.5 nm, 2 nm, 2.5 nm, 3 nm, 3.5 nm, 4 nm, 4.5 nm, 5 nm, 6 nm, 8 nm, 10 nm, 15 nm, 20 nm, 25 nm, 30 nm, 35 nm, 40nm, 50 nm, 70 nm, 85 nm or 100 nm. The desired thickness may be selected according to the application in question.

Molybdenum precursor and reactant may be provided in the reaction chamber in separate steps (104 and 106). FIG. 1B illustrates an embodiment according to the current disclosure, where steps 104 and 106 are separated by purge steps 105 and 107. In such embodiments, a deposition cycle comprises one or more purge steps 105, 107. During purge steps, precursors can be temporally separated from each other by inert gases, such as argon (Ar), nitrogen (N₂) or helium (He) and/or a vacuum pressure. The separation of molybdenum precursor and reactant may alternatively be spatial.

Purging the reaction chamber 103, 105 may prevent or mitigate gas-phase reactions between a molybdenum precursor and a reactant, and enable possible self-saturating surface reactions. Surplus chemicals and reaction byproducts, if any, may be removed from the substrate surface, such as by purging the reaction chamber or by moving the substrate, before the substrate is contacted with the next reactive chemical. In some embodiments, however, the substrate may be moved to separately contact a molybdenum precursor and a reactant. Because, in some embodiments, the reactions may self-saturate, strict temperature control of the substrates and precise dosage control of the precursors and reactants may not be required. However, the substrate temperature is preferably such that an incident gas species does not condense into monolayers or multimonolayers nor thermally decompose on the surface.

When performing the method 100, a material comprising molybdenum is deposited into a gap on the substrate. The deposition process may be a cyclical deposition process, and may include cyclical CVD, ALD, or a hybrid cyclical CVD/ALD process. In some embodiments, the growth rate of a particular ALD process may be low compared with a CVD process. One approach to increase the growth rate may be that of operating at a higher deposition temperature than that typically employed in an ALD process, resulting in some portion of a chemical vapor deposition process, but still taking advantage of the sequential introduction of a molybdenum precursor and a reactant. Such a process may be referred to as cyclical CVD. In some embodiments, a cyclical CVD process may comprise the introduction of two or more precursors into the reaction chamber, wherein there may be a time period of overlap between the two or more precursors in the reaction chamber resulting in both an ALD component of the deposition and a CVD component of the deposition. This is referred to as a hybrid process.

In some embodiments, a cyclical deposition process may comprise the continuous flow of one reactant or precursor and the periodic pulsing of the other chemical component into the reaction chamber. In some embodiments, the reactant is continuously provided into the reaction chamber and the molybdenum precursor is periodically pulsed. The temperature and/or pressure within a reaction chamber during step 104 can be the same or similar to any of the pressures and temperatures noted above in connection with step 102.

In some embodiments, the molybdenum precursor is brought into contact with a substrate surface 104, excess molybdenum precursor is partially or substantially completely removed by an inert gas or vacuum 105, and reactant is brought into contact with the substrate surface comprising the molybdenum precursor. Molybdenum precursor may be brought in to contact with the substrate surface in one or more pulses 104. In other words, pulsing of the molybdenum precursor 104 may be repeated. The molybdenum precursor on the substrate surface may react with the reactant to form a material comprising molybdenum on the substrate surface. Also, pulsing of the reactant 106 may be repeated. In some embodiments, reactant may be provided in the reaction chamber first 106. Thereafter, the reaction chamber may be purged 105 and molybdenum precursor provided in the reaction chamber in one or more pulses 104.

In some embodiments, if a material comprising molybdenum is deposited at a temperature of between 370 to 410 °C, and the deposition cycle (providing molybdenum precursor and reactant, separated by purging) is repeated between 400 and 600 times, it may be possible to obtain a material with a thickness between approximately 10nm and 40nm, for example 20nm or 30nm.

The properties of a film may be modified by using a post-deposition anneal. Annealing may be performed directly after depositing of a material, i.e., without additional layers being deposited. Alternatively, annealing may be performed after additional layers have been deposited. An annealing temperature from about 600 °C to about 800 °C may be used. In some embodiments, an annealing temperature may be 600 °C, 630 °C, 660 °C, 700 °C, 730 °C or 750 °C. Annealing may be performed in a gas atmosphere comprising, consisting essentially of, or consisting of argon, an argon-hydrogen mixture, hydrogen, nitrogen or a nitrogen-hydrogen mixture. The duration of annealing may be from about 1 minute to about 60 minutes, for example, 5 minutes, 20 minutes, 30 minutes, or 45 minutes. An annealing may be performed at a pressure of 0.05 to 760 Torr. In some embodiments, a pressure during annealing may be about 1 Torr, about 10 Torr, about 100 Torr or about 500 Torr. When annealing the molybdenum-containing material, molybdenum silicide material is formed using the silicon from the substrate.

In some embodiments, the process further comprises a preclean step. The preclean is performed before step 104 of providing the molybdenum precursor into the reaction chamber. The preclean step removes any native oxide from the surface of the substrate. In some embodiments, the preclean is performed by remote plasma treatment, radical treatment or hydrogen fluoride treatment. In some embodiments, the radical treatment comprises treating the surface with radicals obtained from NH₃ gas and/or NF₃ gas. In some embodiments, the preclean comprises hydrogen fluoride vapor and NH₃ gas. In yet another embodiment the preclean comprises a sputter etch using argon gas or a mixture of argon gas and NH₃ gas.

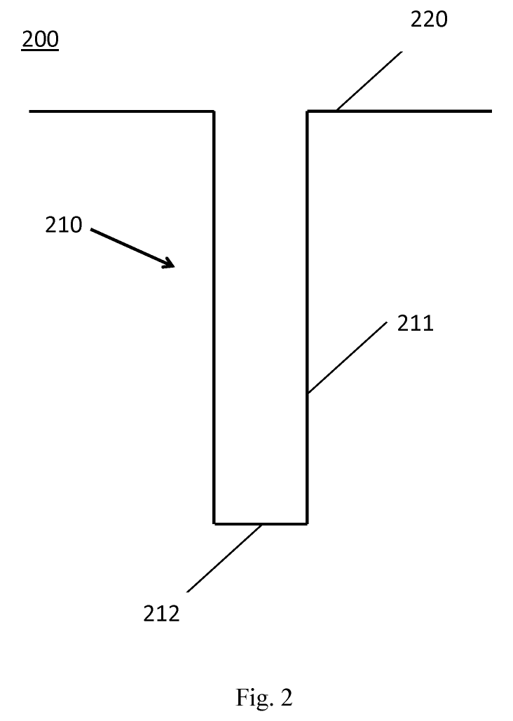

FIG. 2 shows a schematic representation of a substrate (200) comprising a gap (210). The gap (210) comprises a sidewall (211) and a bottom (212). The substrate further comprises a proximal surface (220). In some embodiments, the sidewall (211) and the bottom (212) comprise a different material. In some embodiments, the sidewall (211) comprises a dielectric material. In some embodiments, the sidewall (211) comprises a silicon-containing dielectric material, e.g., silicon oxide, silicon nitride, silicon carbide, and mixtures thereof. In some embodiments, the sidewall (211) comprises a metal, such as a molybdenum, a post-molybdenum metal, or a rare earth metal. In some embodiments, the metal comprises Cu, Co, W, Ru, Mo, Al, or an alloy thereof. In some embodiments, the bottom (212) comprises silicon.

In some embodiments, the proximal surface (220) has the same composition as the sidewall (211). In some embodiments, the proximal surface (220) has a different composition than the sidewall (211). In some embodiments, the proximal surface (220) has a different composition than the bottom (212). In some embodiments, the proximal surface (220) has the same composition as the bottom (212).

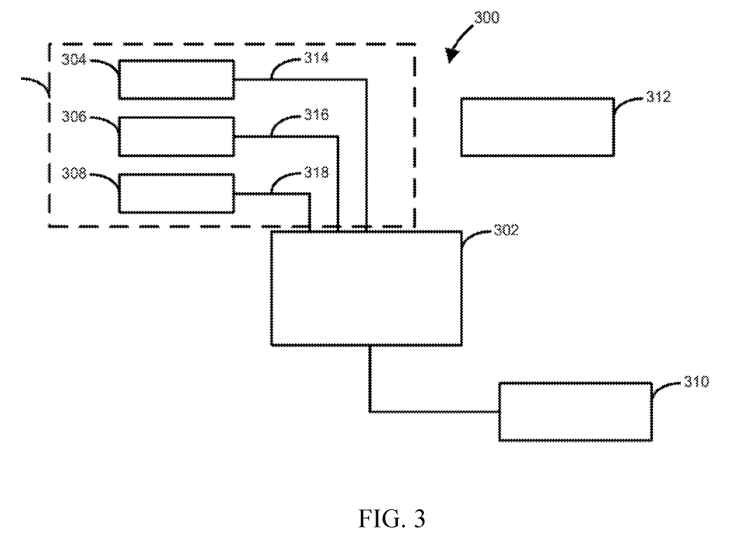

FIG. 3 illustrates a semiconductor processing apparatus 300 according to the current disclosure in a schematic manner. Semiconductor processing apparatus 300 can be used to perform a method as described herein and/or to form a structure or a device, or a portion thereof as described herein.

In the illustrated example, semiconductor processing apparatus 300 includes one or more reaction chambers 302, a precursor injector system 301, a molybdenum precursor vessel 304, reactant vessel 306, a purge gas source 308, an exhaust source 310, and a controller 312.

Reaction chamber 302 can include any suitable reaction chamber, such as an ALD or CVD reaction chamber.

The molybdenum precursor vessel 304 can include a vessel and one or more molybdenum precursors as described herein – alone or mixed with one or more carrier (e.g., inert) gases. Reactant vessel 306 can include a vessel and one or more reactants as described herein – alone or mixed with one or more carrier gases. Purge gas source 308 can include one or more inert gases as described herein. Although illustrated with three source vessels 304-308, semiconductor processing apparatus 300 can include any suitable number of source vessels. Source vessels 304-308 can be coupled to reaction chamber 302 via lines 314-318, which can each include flow controllers, valves, heaters, and the like. In some embodiments, the molybdenum precursor in the molybdenum precursor vessel may be heated. In some embodiments, the vessel is heated so that the molybdenum precursor reaches a temperature between about 60 °C and about 160 °C, such as between about 100 °C and about 145 °C, for example, 85 °C, 100 °C, 110 °C, 120 °C, 130 °C or 140 °C.

Exhaust source 310 can include one or more vacuum pumps.

Controller 312 includes electronic circuitry and software to selectively operate valves, manifolds, heaters, pumps and other components included in the semiconductor processing apparatus 300 to carry out a method as disclosed herein. Such circuitry and components operate to introduce precursors and purge gases from the respective sources 304-308. Controller 312 can control timing of gas pulse sequences, temperature of the substrate and/or reaction chamber 302, pressure within the reaction chamber 302, and various other operations to provide proper operation of the semiconductor processing apparatus 300. Controller 312 can include control software to electrically or pneumatically control valves to control flow of precursors and purge gases into and out of the reaction chamber 302. Controller 312 can include modules such as a software or hardware component, which performs certain tasks. A module may be configured to reside on the addressable storage medium of the control system and be configured to execute one or more processes.

Other configurations of semiconductor processing apparatus 300 are possible, including different numbers and kinds of precursor and reactant sources and purge gas sources. Further, it will be appreciated that there are many arrangements of valves, conduits, precursor sources, and purge gas sources that may be used to accomplish the goal of selectively and in coordinated manner feeding gases into reaction chamber 302. Further, as a schematic representation of a semiconductor processing apparatus, many components have been omitted for simplicity of illustration, and such components may include, for example, various valves, manifolds, purifiers, heaters, containers, vents, and/or bypasses.

During operation of semiconductor processing apparatus 300, substrates, such as semiconductor wafers (not illustrated), are transferred from, e.g., a substrate handling system to reaction chamber 302. Once substrate(s) are transferred to reaction chamber 302, one or more gases from gas sources 304-308, such as precursors, reactants, carrier gases, and/or purge gases, are introduced into reaction chamber 302.

The illustrations presented herein are not meant to be actual views of any particular material, structure, or device, but are merely idealized representations that are used to describe embodiments of the disclosure.

The particular implementations shown and described are illustrative of the invention and its best mode and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationship or physical connections may be present in the practical system, and/or may be absent in some embodiments.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject matter of the present disclosure includes all novel and nonobvious combinations and subcombinations of the various processes, systems, and configurations, and other features, functions, acts, and/or properties disclosed herein, as well as any and all equivalents thereof.

1. A method for selectively filling a gap with molybdenum-containing material, comprising
providing a substrate into a reaction chamber, wherein the substrate comprises at least one gap, wherein the gap comprises a silicon surface and a dielectric surface; and
executing at least one deposition cycle, wherein a deposition cycle comprises:
providing a molybdenum precursor into the reaction chamber in vapor phase; and
providing a reactant into the reaction chamber in vapor phase,
wherein the molybdenum-containing material is selectively deposited on the silicon surface of the gap to at least partially fill the gap.

2. The method according to claim 1, further comprising a thermal anneal step, wherein the substrate is heated to a temperature of at least 550 °C.

3. The method according to claim 1, wherein the substrate is heated to a temperature between 350 °C and 550 °C during the deposition cycle.

4. The method according to claim 1, wherein the molybdenum-containing material comprises molybdenum silicide.

5. The method according to claim 1, further comprising precleaning the silicon-containing substrate to remove native oxide from the surface of the substrate.

6. The method according to claim 5, wherein the precleaning is performed by remote plasma treatment, radical treatment, hydrogen fluoride treatment or sputter etch.

7. The method according to claim 6, wherein the radical treatment comprises treating the surface with radicals obtained from NH₃ gas and/or NF₃ gas.

8. The method according to claim 1, further comprising a purge step after providing the molybdenum precursor and after providing the reactant.

9. The method according to claim 1, wherein the molybdenum precursor is provided into the reaction chamber in pulses and the reactant is provided into the reaction chamber continuously.

10. The method according to claim 1, wherein the gap comprises a bottom and at least two sidewalls, and wherein the bottom comprises silicon, silicon-germanium, germanium, or doped forms thereof, and the at least two sidewalls comprise a dielectric material.

11. The method according to claim 10, wherein the dielectric material is selected from the group consisting of silicon oxynitride, silicon oxide, silicon nitride, silicon oxycarbide and aluminum oxide.

12. The method according to claim 1, wherein the gap is vertically or horizontally oriented relative to a proximal surface of the substrate.

13. The method according to claim 1, further comprising depositing a second material into the gap, wherein the second material comprises metallic molybdenum.

14. The method according to claim 13, wherein the second material is deposited on top of the molybdenum-containing material.

15. The method according to claim 13, wherein the second material is deposited by executing at least one deposition cycle, wherein a deposition cycle comprises:
providing a molybdenum precursor into the reaction chamber in vapor phase; and
providing a reactant into the reaction chamber in vapor phase,
wherein the pressure in the reaction chamber is greater during deposition of the second material than during deposition of molybdenum-containing material.

16. The method according to claim 1, wherein the molybdenum precursor comprises a molybdenum halide.

17. The method according to claim 16, wherein the molybdenum halide comprises molybdenum pentachloride.

18. The method according to claim 1, wherein the reactant comprises hydrogen.

19. A semiconductor processing apparatus comprising:
a reaction chamber comprising a substrate support for supporting a substrate;
a heater constructed and arranged to heat the substrate in the reaction chamber;
a molybdenum precursor source containing a molybdenum precursor in fluid connection with the reaction chamber via one or more precursor valves;
a reactant source containing a reactant in fluid connection with the reaction chamber via one or more reactant valves; and
a controller configured for causing the semiconductor processing apparatus to perform a method according to claim 1.
